(19) United States
(12) Patent Application Publication
(10) Pub. No.: US 2024/0376588 A1
(43) Pub. Date: Nov. 14, 2024

(54) EVAPORATION MASK, EVAPORATION DEVICE, AND EVAPORATION METHOD

(71) Applicant: BOE Technology Group Co., Ltd., Beijing (CN)

(72) Inventors: Xiaohu LI, Beijing (CN); Yan QU, Beijing (CN); Liangliang KANG, Beijing (CN); Qian JIN, Beijing (CN); Lu WANG, Beijing (CN); Weijie WANG, Beijing (CN); Zhiqiang JIAO, Beijing (CN)

(73) Assignee: BOE Technology Group Co., Ltd., Beijing (CN)

(21) Appl. No.: 18/696,355

(22) PCT Filed: Jul. 28, 2023
(86) PCT No.: PCT/CN2023/110027

§ 371 Date: Mar. 27, 2024

(30) Foreign Application Priority Data
Aug. 29, 2022 (CN) 202211043493.8

(51) Int. Cl. C23C 14/04; H10K 71/16

(52) U.S. Cl. CPC C23C 14/042; H10K 71/166

(57) ABSTRACT

Provided is an evaporation mask, including a mask plate and a plurality of evaporation through-holes. The evaporation through-holes penetrate through the mask plate and corresponds to the sub-pixel regions one by one such that a plurality of sub-pixels of different colors are formed in the plurality of sub-pixel regions; and wherein for each of the evaporation through-holes, an aperture of an opening of the evaporation through-hole on a side proximal to the to-be-evaporated substrate is less than an aperture of an opening of the evaporation through-hole on a side distal to the to-be-evaporated substrate, the opening of the evaporation through-hole on the side distal to the to-be-evaporated substrate extends to at least one adjacent sub-pixel region, and a color of a sub-pixel evaporated in a sub-pixel region corresponding to the evaporation through-hole is different from a color of a sub-pixel evaporated in the at least one adjacent sub-pixel region.

### CROSS-REFERENCE TO RELATED APPLICATIONS

The present disclosure is a U.S. national stage of international application No. PCT/CN2023/110027, filed on Jul. 28, 2023, which claims priority to Chinese Patent Application No. 202211043493.8, filed on Aug. 29, 2022 and entitled “VAPOR DEPOSITION MASK, VAPOR DEPOSITION APPARATUS AND VAPOR DEPOSITION METHOD”, the disclosures of which are incorporated herein by reference in their entireties.

### TECHNICAL FIELD

The present disclosure relates to the technical field of evaporation, and in particular, relates to an evaporation mask, an evaporation device, and an evaporation method.

### BACKGROUND

In the process of manufacturing an organic light-emitting diode (OLED) display panel, an evaporation device combined with the evaporation process is used to form a required functional film layer on a to-be-evaporated substrate by means of evaporation.

### SUMMARY

Provided are an evaporation mask, an evaporation device, and an evaporation method. The technical solutions are as follows.

According to some embodiments, an evaporation mask is provided. The evaporation mask is applicable to a side of a to-be-evaporated substrate, and the to-be-evaporated substrate is provided with a plurality of sub-pixel regions spaced apart from each other; the evaporation mask includes a mask plate and a plurality of evaporation through-holes;

the plurality of evaporation through-holes penetrates through the mask plate, and corresponds to the plurality of sub-pixel regions one by one such that a plurality of sub-pixels of different colors are formed by an evaporation source evaporating in the plurality of sub-pixel regions; and

wherein for each of the evaporation through-holes, an aperture of an opening of the evaporation through-hole on a side proximal to the to-be-evaporated substrate is less than an aperture of an opening of the evaporation through-hole on a side distal to the to-be-evaporated substrate, the opening of the evaporation through-hole on the side distal to the to-be-evaporated substrate extends to at least one adjacent sub-pixel region, and color of a sub-pixel evaporated in a sub-pixel region corresponding to the evaporation through-hole is different from a color of a sub-pixel evaporated in the at least one adjacent sub-pixel region.

In some embodiments, the plurality of sub-pixel regions are arranged in an array, and a plurality of sub-pixels evaporated in the plurality of sub-pixel regions include a plurality of sub-pixels of three colors, and the sub-pixels are sequentially arranged in an order of every three sub-pixels of different colors in a row direction; and the opening of each evaporation through-hole on the side distal to the to-be-evaporated substrate extends to two adjacent sub-pixel regions.

In some embodiments, the distance between openings of each two adjacent evaporation through-holes on the side distal to the to-be-evaporated substrate is greater than the distance between two sub-pixels formed in two sub-pixel regions corresponding to the two adjacent evaporation through-holes.

In some embodiments, the evaporation through-hole includes two through-hole angles disposed oppositely in a direction parallel to the to-be-evaporated substrate; and

the two through-hole angles of the evaporation through-hole are unequal, and in the two through-hole angles of the evaporation through-hole, a through-hole angle proximal to an upstream direction in which the evaporation source moves is less than a through-hole angle distal to the upstream direction in which the evaporation source moves.

In some embodiments, in the two through-hole angles of the evaporation through-hole, one through-hole angle is a right angle, and another through-hole angle is an acute angle; or both the two through-hole angles of the evaporation through-hole are acute angles.

In some embodiments, in the two through-hole angles of the evaporation through-hole, the smallest through-hole angle is greater than or equal to an arc tangent value of a ratio of the thickness of the mask plate to a first aperture, and is less than or equal to an arc tangent value of a ratio of the thickness of the mask plate to a second aperture;

and the first aperture is an aperture of the opening of the evaporation through-hole on the side distal to the to-be-evaporated substrate in a case that the opening of the evaporation through-hole on the side distal to the to-be-evaporated substrate extends to one adjacent sub-pixel region; and the second aperture is an aperture of the opening of the evaporation through-hole on the side distal to the to-be-evaporated substrate in a case that the opening of the evaporation through-hole on the side distal to the to-be-evaporated substrate extends to two or more adjacent sub-pixel regions.

In some embodiments, the cross-section of the evaporation through-hole is trumpet-shaped in a direction perpendicular to the to-be-evaporated substrate.

In some embodiments, the evaporation through-hole includes a plurality of sub-through-holes spaced apart from each other along a direction parallel to the to-be-evaporated substrate; and

wherein openings of the plurality of sub-through-holes on the side proximal to the to-be-evaporated substrate are overlapped with each other, and openings of each two adjacent sub-through-holes on the side distal to the to-be-evaporated substrate are spaced apart by the mask plate.

In some embodiments, each of the sub-through-holes includes two through-hole angles disposed oppositely in the direction parallel to the to-be-evaporated substrate, and the two through-hole angles corresponding to each sub-through-hole are equal, and the through-hole angles corresponding to respective sub-through-holes are unequal.

In some embodiments, the evaporation through-hole includes two sub-through-holes;

both two through-hole angles corresponding to one of the two sub-through-holes are acute angles, and both two through-hole angles corresponding to another of the two sub-through-holes are right angles; or

both two through-hole angles corresponding to each of the two sub-through-holes are acute angles.

In some embodiments, an orthographic projection of the opening of the evaporation through-hole on the side proximal to the to-be-evaporated substrate is circular, elliptical or rectangular; and an orthographic projection of the opening of the evaporation through-hole on the side distal to the to-be-evaporated substrate is elliptical or rectangular.

In some embodiments, a ratio of a thickness of the mask plate to the aperture of the opening of the evaporation through-hole on the side distal to the to-be-evaporated substrate is greater than or equal to 2.

In some embodiments, the mask plate includes a frame portion and an opening portion, the frame portion being configured to define the opening portion, and the opening portion being configured to form the plurality of evaporation through-holes; and

wherein a through-hole angle of the evaporation through-hole is less than an angle between the frame portion and the to-be-evaporated substrate.

In some embodiments, the frame portion is made of single crystal silicon, and the opening portion is made of at least one of single crystal silicon, silicon oxide, or silicon nitride.

According to some embodiments, an evaporation device is provided. The evaporation device includes a plurality of evaporation sources, and the evaporation mask according to any of the above embodiments;

the plurality of evaporation sources are disposed on one side of the evaporation mask distal to the to-be-evaporated substrate of a display panel, and the plurality of evaporation sources are arranged at intervals along a direction parallel to the to-be-evaporated substrate;

wherein a nozzle of each evaporation source faces the evaporation mask, the evaporation source is configured to evaporate a material onto a sub-pixel region of the to-be-evaporated substrate through the evaporation through-hole in the evaporation mask so as to form a sub-pixel, and materials evaporated by respective evaporation sources are different;

and an evaporation angle is formed between the nozzle of the evaporation source and the to-be-evaporated substrate, and a difference value between the evaporation angle and the through-hole angle of the evaporation through-hole is less than a difference threshold.

In some embodiments, the evaporation device includes two evaporation sources; the evaporation through-hole includes two through-hole angles disposed oppositely in the direction parallel to the to-be-evaporated substrate; and

the evaporation angle of each evaporation source is equal to one, closer to the evaporation source, of the two through-hole angle of the evaporation through-hole.

In some embodiments, a distance between each two adjacent evaporation sources is negatively correlated with a first parameter and is positively correlated with a second parameter;

wherein the first parameter is the thickness of the mask plate in the evaporation mask; the second parameter is a product of a first sub-parameter and a second sub-parameter; and

the first sub-parameter is, for each two adjacent evaporation sources, a distance between an intersection of a nozzle extension line of one evaporation source and a side of the evaporation through-hole distal to the to-be-evaporated substrate and an intersection of a nozzle extension line of the other evaporation source and the side of the evaporation through-hole distal to the to-be-evaporated substrate, and the second sub-parameter is a sum of the first parameter and a vertical distance between the plurality of evaporation sources and the evaporation mask.

In some embodiments, the distance b between each two adjacent evaporation sources satisfies: b=a(d+Ts)/d; and

where d is the first parameter, a is the first sub-parameter, and Ts is the vertical distance between the plurality of evaporation sources and the evaporation mask.

In some embodiments, the cross-section of the evaporation through-hole is trumpet-shaped in the direction perpendicular to the to-be-evaporated substrate; and

a distance between each two adjacent evaporation sources is negatively correlated with a smallest through-hole angle of the two through-hole angles of the evaporation through-hole.

According to some embodiments, an evaporation method is provided. The evaporation method includes following steps.

a to-be-evaporated substrate is provided; and

a material is evaporated on the to-be-evaporated substrate by adopting the evaporation device according to any of above embodiments to form a plurality of sub-pixels.

### BRIEF DESCRIPTION OF THE DRAWINGS

For clearer descriptions of the technical solutions according to the embodiments of the present invention, the drawings required to be used in the description of the embodiments are briefly introduced below. It is apparent that the drawings in the description below are only some embodiments of the present invention, and for those of ordinary skill in the art, other drawings may be obtained from the drawings without creative efforts.

FIG. 1 is a schematic structural diagram of an evaporation device according to some embodiments of the present disclosure;

FIG. 2 is a schematic structural diagram of an evaporation mask according to some embodiments of the present disclosure;

FIG. 3 is a schematic structural diagram of another evaporation mask according to some embodiments of the present disclosure;

FIG. 4 is an equivalent structure diagram of the evaporation mask in the structure shown in FIG. 3;

FIG. 5 is an equivalent cross-sectional view of the evaporation mask in the structure shown in FIG. 3;

FIG. 6 is an equivalent top view of the evaporation mask in the structure shown in FIG. 3;

FIG. 7 is an equivalent bottom view of the evaporation mask in the structure shown in FIG. 3;

FIG. 8 is a schematic structural diagram of still another evaporation mask according to some embodiments of the present disclosure;

FIG. 9 is an equivalent structure diagram of the evaporation mask in the structure shown in FIG. 8;

FIG. 10 is an equivalent cross-sectional view of the evaporation mask in the structure shown in FIG. 8;

FIG. 11 is an equivalent top view of the evaporation mask in the structure shown in FIG. 8;

FIG. 12 is an equivalent bottom view of the evaporation mask in the structure shown in FIG. 8;

FIG. 13 is a schematic structural diagram of yet another evaporation mask according to some embodiments of the present disclosure;

FIG. 14 is an equivalent structure diagram of the evaporation mask in the structure shown in FIG. 13;

FIG. 15 is an equivalent cross-sectional view of the evaporation mask in the structure shown in FIG. 13;

FIG. 16 is an equivalent top view of the evaporation mask in the structure shown in FIG. 13;

FIG. 17 is an equivalent bottom view of the evaporation mask in the structure shown in FIG. 13;

FIG. 18 is a schematic structural diagram of yet another evaporation mask according to some embodiments of the present disclosure;

FIG. 19 is an equivalent structure diagram of the evaporation mask in the structure shown in FIG. 18;

FIG. 20 is an equivalent cross-sectional view of the evaporation mask in the structure shown in FIG. 18;

FIG. 21 is an equivalent top view of the evaporation mask in the structure shown in FIG. 18;

FIG. 22 is an equivalent bottom view of the evaporation mask in the structure shown in FIG. 18;

FIG. 23 is a schematic structural diagram of yet another evaporation mask according to some embodiments of the present disclosure;

FIG. 24 is a schematic structural diagram of an evaporation device according to some embodiments of the present disclosure;

FIG. 25 is a schematic structural diagram of another evaporation device according to some embodiments of the present disclosure;

FIG. 26 is a schematic structural diagram of still another evaporation device according to some embodiments of the present disclosure;

FIG. 27 is a schematic structural diagram of yet another evaporation device according to some embodiments of the present disclosure;

FIG. 28 is a schematic diagram of a display panel including a pixel definition layer according to some embodiments of the present disclosure;

FIG. 29 is a schematic diagram of an evaporation device with reusing a pixel definition layer as an evaporation mask according to some embodiments of the present disclosure; and

FIG. 30 is a flowchart of an evaporation method according to some embodiments of the present disclosure.

### DETAILED DESCRIPTION

For clearer descriptions of the objects, technical solutions, and advantages of the present disclosure, the embodiments of the present disclosure are further described in detail below with reference to the drawings.

The evaporation device generally includes an evaporation source and an evaporation mask. The evaporation mask is provided with an evaporation through-hole perpendicular to the to-be-evaporated substrate. The evaporation source is configured to evaporate materials onto the to-be-evaporated substrate through the evaporation through-hole so as to form the required functional film layer. In addition, for a functional film layer formed by doping different materials, the evaporation device generally includes a plurality of evaporation sources capable of evaporating different materials, the plurality of evaporation sources being configured to evaporate different materials onto the to-be-evaporated substrate through the same evaporation through-hole.

In some practices, functional film layers in the OLED display panel generally need to be formed by co-doping materials, that is, different materials need to be doped to form a certain functional film layer. Accordingly, a plurality of evaporation sources capable of evaporating different materials needs to be adopted for co-evaporation (i.e., co-vaporization) in the process of manufacturing a film layer. For example, a common material co-doped film layer includes a light-emitting layer included in a pixel in a display panel. In addition, the doped different materials may be divided into a main material and a doped material, the proportion of the main material being greater than that of the doped material. Accordingly, a plurality of evaporation sources are divided into at least one main evaporation source (i.e., a main source) configured to evaporate a main material and at least one doped evaporation source (i.e., a doped source) configured to evaporate a doped material.

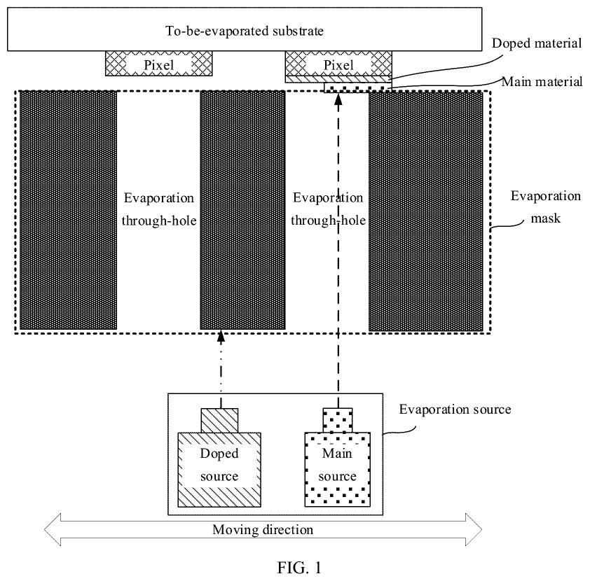

For example, the evaporation device shown in FIG. 1 includes one main source and one doped source. Each evaporation source is provided with an evaporation crucible, into which a material to be evaporated is filled in advance, and a nozzle. Subsequently, the evaporation source evaporates the material filled in the evaporation crucible through the nozzle along a certain direction, which is the same as the direction of the nozzle and is referred to as the evaporation direction. In addition, a plurality of evaporation sources are disposed in the same evaporation chamber and move back and forth along the moving direction parallel to the to-be-evaporated substrate so as to form functional film layers at different positions of the to-be-evaporated substrate respectively.

However, as the evaporation through-holes of the existing evaporation mask are all straight holes as shown in FIG. 1, that is, the evaporation through-holes are perpendicular to the to-be-evaporated substrate and have vertical interiors, each two adjacent evaporation sources cannot be infinitely close, and a distance between each two adjacent evaporation through-holes is small and the aperture of each evaporation through-hole is greater than the distance, the layering phenomenon shown in FIG. 1 appears in the materials evaporated by a plurality of evaporation sources through the same evaporation through-hole, and then the materials cannot be co-doped reliably, that is, doping of multi-sources (i.e., evaporation sources) cannot be achieved, and accordingly, the formed functional film layer is unavailable, resulting in degraded performance of devices including the functional film layer. The distance between each two adjacent evaporation through-holes is generally about 4 microns (μm), such as 4.6 μm or 4.76 μm. The aperture of each evaporation through-hole is generally about 7 μm, such as 7.14 μm or 7.22 μm. The above problems are more easily caused in scenarios for manufacturing a film layer with high pixel density and small equipment distance. The equipment distance is the vertical distance between the evaporation source and the evaporation mask and is also referred to as the smallest distance.

Embodiments of the present disclosure provide a novel evaporation mask. By adopting the evaporation mask, multi-source doping can be reliably achieved, a functional film layer with co-doped materials is manufactured, and good device performance is ensured.

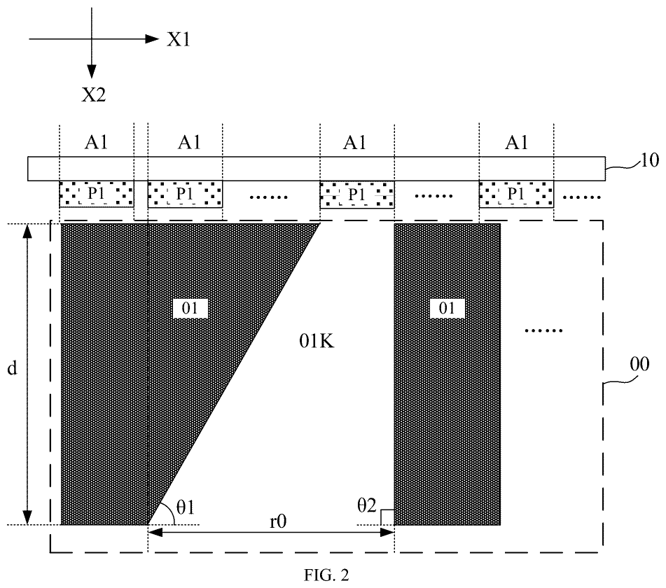

FIG. 2 is a schematic structural diagram of an evaporation mask according to some embodiments of the present disclosure. As shown in FIG. 2, the evaporation mask 00 is configured to be arranged on one side of a to-be-evaporated substrate 10, and the to-be-evaporated substrate 10 is provided with a plurality of sub-pixel regions A1 arranged spaced apart from each other. The evaporation mask 00 includes:

a mask plate 01;

and a plurality of evaporation through-holes 01K (only one evaporation through-hole 01K is schematically illustrated in the figure) penetrating through the mask plate 01, wherein the plurality of evaporation through-holes 01K correspond to the plurality of sub-pixel regions A1 one by one such that a plurality of sub-pixels P1 of different colors are formed by an evaporation source evaporating in the plurality of sub-pixel regions A1. That is, the evaporation source evaporates a material in a corresponding sub-pixel region A1 on the to-be-evaporated substrate 10 through the evaporation through-hole 01K to form a sub-pixel P1, and evaporates materials in different sub-pixel regions A1 through different evaporation through-holes 01K to form a plurality of sub-pixels P1. As the plurality of sub-pixel regions A1 are spaced apart from each other, the plurality of evaporation through-holes 01K corresponding to the plurality of sub-pixel regions A1 one by one are also spaced apart from each other, and the plurality of sub-pixels P1 as formed are also spaced apart from each other.

The aperture of the opening (i.e., an upper opening shown in FIG. 2) of the evaporation through-hole 01K on the side proximal to the to-be-evaporated substrate 10 is less than the aperture of the opening (i.e., a lower opening shown in FIG. 2) of the evaporation through-hole 01K on a side distal to the to-be-evaporated substrate 10. It can be seen that at least one inner wall of the evaporation through-hole 01K intersects with the to-be-evaporated substrate 10, but is not perpendicular thereto, that is, the evaporation through-hole 01K is not a straight hole but an inclined hole. The evaporation source is generally disposed on the side of the mask plate 01 distal to the to-be-evaporated substrate 10, so the upper opening is considered as an opening distal to the evaporation source, and the lower opening is considered as an opening proximal to the evaporation source. The material evaporated by the evaporation source enters the evaporation through-hole 01K by passing through the lower opening, and is then formed in the sub-pixel region A1 of the to-be-evaporated substrate 10 by passing through the upper opening.

In addition, the opening of the evaporation through-hole 01K on the side distal to the to-be-evaporated substrate 10 extends to at least one adjacent sub-pixel region A1, that is, the orthographic projection of the opening of the evaporation through-hole 01K on the side distal to the to-be-evaporated substrate 10 onto the to-be-evaporated substrate 10 is overlapped with the at least one adjacent sub-pixel region A1. In addition, the color of the sub-pixel P1 evaporated in the sub-pixel region A1 corresponding to the evaporation through-hole 01K is different from the color of the sub-pixel P1 evaporated in the at least one adjacent sub-pixel region A1.

In this way, the nozzle orientation of the evaporation source for evaporating the material is flexibly set based on the through-hole angles (also referred to as mask inclination angles) of the evaporation through-hole 01K, that is, the evaporation angle is flexibly controlled, such that in the case that a sub-pixel P1 of any color is formed, the evaporation source can reliably evaporate the material in a corresponding sub-pixel region A1 through the evaporation through-hole 01K so as to form the sub-pixel P1 without affecting the formation of the sub-pixels P1 of other colors. In addition, in an application scenario where a plurality of evaporation sources evaporate different materials through the evaporation through-holes 01K to form a certain film layer (e.g., a light-emitting layer) of the sub-pixel P1 by co-doping the materials, the evaporation through-holes 01K are set to satisfy the shape shown in FIG. 2, the through-hole angles are flexibly set, and the evaporation angles of the evaporation sources are adjusted accordingly, such that different materials evaporated by the plurality of evaporation sources can be reliably doped on the to-be-evaporated substrate 10, thereby avoiding material layering. Herein, the through-hole angles of the evaporation through-hole 01K refer to two angles (identified as θ1 and θ2 in the figure) of the evaporation through-hole 01K in a direction X1 parallel to the to-be-evaporated substrate 10, and belong to angles formed by two opposite inner walls of the evaporation through-hole 01K in the direction parallel to the to-be-evaporated substrate 10 and the to-be-evaporated substrate 10.

It should be noted that, referring to FIG. 2, the ratio of the thickness d of the mask plate 01 to the aperture r0 of the opening of the evaporation through-hole 01K on the side distal to the to-be-evaporated substrate 10 is large, that is, the mask plate 01 is thick, and the aperture of the opening of the evaporation through-hole 01K on the side distal to the to-be-evaporated substrate 10 is small. In this application scenario, in the case that the evaporation through-hole 01K is a straight hole as shown in FIG. 1, co-doping of the materials is difficult to complete, and in the case that the evaporation through-hole 01K is a non-straight hole as shown in FIG. 2, co-doping of the materials can be reliably completed by flexibly setting through-hole angles without being influenced by the thickness of the mask plate 01 and the small aperture of the lower opening. The thickness direction is a direction X2 perpendicular to the to-be-evaporated substrate 10.

In some embodiments, an evaporation mask 00 having the evaporation through-hole 01K shown in FIG. 2 is formed by a single patterning process. The single patterning process includes: sequentially gluing, exposing, developing, etching, etc. The to-be-evaporated substrate 10 is a glass substrate or a flexible substrate, which is also referred to as a preparation substrate.

In summary, the embodiments of the present disclosure provide an evaporation mask. The evaporation mask includes a mask plate, and a plurality of evaporation through-holes penetrating through the mask plate. The plurality of evaporation through-holes correspond to a plurality of sub-pixel regions spaced apart from each other on a to-be-evaporated substrate one by one such that a plurality of sub-pixels of different colors are formed by an evaporation source evaporating in the plurality of sub-pixel regions. As an opening of each evaporation through-hole on the side proximal to the to-be-evaporated substrate has a smaller aperture than an opening of the evaporation through-hole on the side distal to the to-be-evaporated substrate, and can extend to at least one adjacent sub-pixel region with formed sub-pixels of different colors, the through-hole angles of the evaporation through-holes are flexibly set, and the evaporation angles of the evaporation sources are adjusted accordingly, such that a plurality of evaporation sources reliably evaporate different materials onto the to-be-evaporated substrate, and the different evaporated materials can be reliably co-doped, thereby providing a good evaporation effect.

In some embodiments, referring to FIG. 2, in the embodiments of the present disclosure, the ratio of the thickness d of the mask plate 01 to the aperture r0 of the opening of the evaporation through-hole 01K on the side distal to the to-be-evaporated substrate 10 is greater than or equal to 2. For example, the thickness d of the mask plate 01 is 20 micrometers (μm), and the aperture r0 of the opening is 4 μm.

In some embodiments, a plurality of sub-pixel regions A1 of the to-be-evaporated substrate 10 are arranged in an array, i.e., in rows and columns, including a plurality of rows and a plurality of columns of sub-pixel regions A1. Accordingly, a plurality of sub-pixels P1 formed in the plurality of sub-pixel regions A1 are arranged in rows and columns, including a plurality of rows and a plurality of columns of sub-pixels P1.

For example, the plurality of sub-pixels P1 formed by evaporation in the plurality of sub-pixel regions A1 include a plurality of sub-pixels P1 of three colors. In addition, in the row direction X1 (the same direction as parallel to the to-be-evaporated substrate 10), the sub-pixels P1 are sequentially arranged in the order of every three sub-pixels of different colors. The opening of the evaporation through-hole 01K on the side distal to the to-be-evaporated substrate 10 extends to two adjacent sub-pixel regions A1. That is, the opening extends to all adjacent sub-pixel regions A1 with different colors.

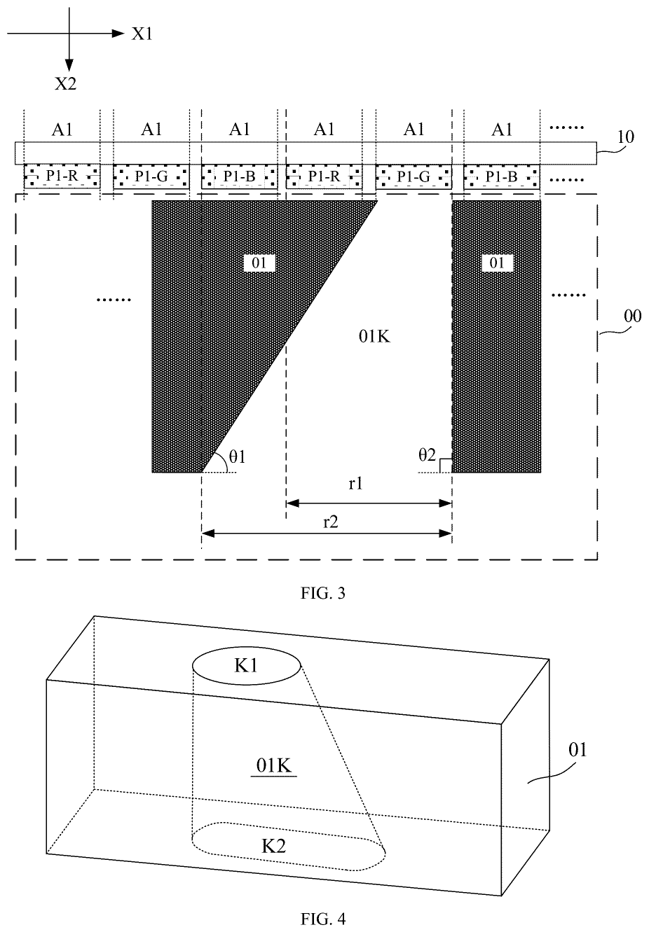

For example, referring to FIG. 3, three colors shown are red (R), green (G), and blue (B), respectively, and in the row direction X1, the sub-pixels P1 formed on the same row are sequentially arranged in the order of one red sub-pixel P1-R, one green sub-pixel P1-G, and one blue sub-pixel P1-B. In addition, the positions of red, green, and blue are interchangeable. The opening of the evaporation through-hole 01K on the side distal to the to-be-evaporated substrate 10, corresponding to the sub-pixel region A1 where the green sub-pixel P1-G is located, extends to two adjacent sub-pixel regions A1, and the sub-pixels P1 formed in the two sub-pixel regions A1 are a red sub-pixel P1-R and a blue sub-pixel P1-B, respectively. Other evaporation through-holes 01K are the same, and are not repeated herein.

In addition, in some other embodiments, for the scenario of sub-pixels P1 of three colors as shown in FIG. 3, the opening of the evaporation through-hole 01K on the side distal to the to-be-evaporated substrate 10 also extends to only one adjacent sub-pixel region A1. That is, the opening of the evaporation through-hole 01K on the side distal to the to-be-evaporated substrate 10 at least extends to an adjacent sub-pixel region A1 and at most extends to two adjacent sub-pixel regions A1, so as to ensure that the opening does not extend to the sub-pixel regions A1 where the formed sub-pixels have the same color, thereby avoiding affecting the evaporation effect.

In addition, in some other embodiments, the plurality of sub-pixels P1 formed by evaporation in the plurality of sub-pixel regions A1 further include a plurality of sub-pixels P1 of other numbers of colors, such as, red (R), green (G), blue (B), and white (W). In the row direction X1, in the case that the sub-pixels Pl are sequentially arranged in the order of one red sub-pixel P1-R, one green sub-pixel P1-G, one blue sub-pixel P1-B and one white sub-pixel, the opening of the evaporation through-hole 01K on the side distal to the to-be-evaporated substrate 10 extends to at least one adjacent sub-pixel region A1, or two adjacent sub-pixel regions A1, or at most three adjacent sub-pixel regions A1.

In some embodiments, referring to FIG. 3, in the embodiments of the present disclosure, the distance between openings of each two adjacent evaporation through-holes 01K on the sides distal to the to-be-evaporated substrate 10 is greater than the distance between two sub-pixels P1 formed in two sub-pixel regions A1 corresponding to the two adjacent evaporation through-holes 01K. Therefore, it can be ensured that the evaporation source reliably evaporates the material in the corresponding sub-pixel region A1 through the evaporation through-hole 01K, and the materials are prevented from being layered when different materials are evaporated, that is, different evaporated materials can be reliably co-doped.

In some embodiments, as described in the above embodiments, in a direction parallel to the to-be-evaporated substrate 10, the evaporation through-hole 01K includes two opposite through-hole angles, which are identified as θ1 and θ2 in FIGS. 2 and 3, respectively.

The two through-hole angles θ1 and θ2 of the evaporation through-hole 01K are unequal. In addition, referring to FIGS. 2 to 3, in the two through-hole angles θ1 and θ2 of the evaporation through-hole 01K, the through-hole angle θ1 close to the upstream direction in which the evaporation source moves (i.e., the through-hole angle θ1 proximal to the doped source in FIG. 1) is less than the through-hole angle θ2 distal to the upstream direction in which the evaporation source moves (i.e., the through-hole angle θ2 proximal to the main source in FIG. 1). Therefore, co-doping of different materials evaporated by a plurality of evaporation sources is achieved more easily, and good reliability of co-doping is ensured.

In some embodiments, in the two through-hole angles θ1 and θ2 of the evaporation through-hole 01K, one through-hole angle is a right angle, which is equal to 90 degrees; and the other through-hole angle is an acute angle, which is greater than 0 degrees and less than 90 degrees. Or, in the two through-hole angles θ1 and θ2 of the evaporation through-hole 01K, each through-hole angle is an acute angle, which is greater than 0 degrees and less than 90 degrees.

For example, referring to FIGS. 2 and 3, the evaporation through-hole 01K shown includes two through-hole angles θ1 and θ2, the through-hole angle θ1 being an acute angle, and the through-hole angle θ2 being a right angle.

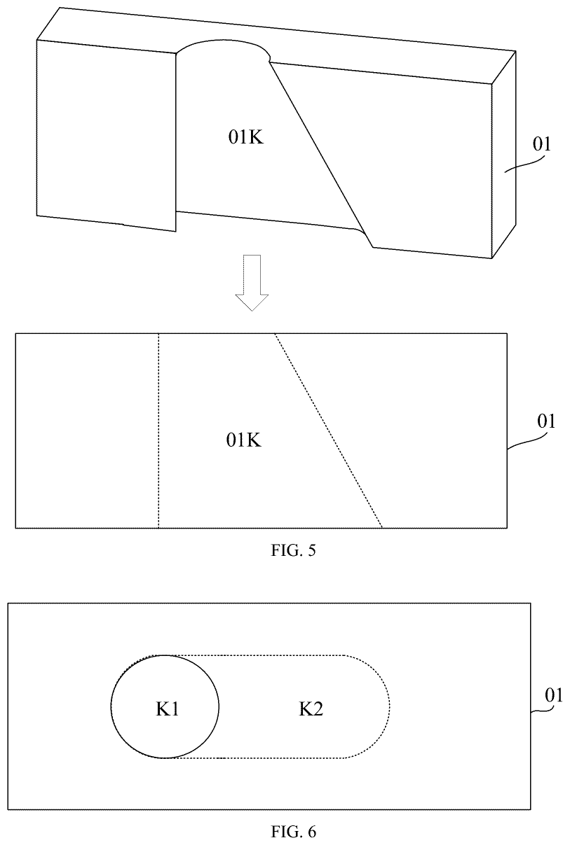

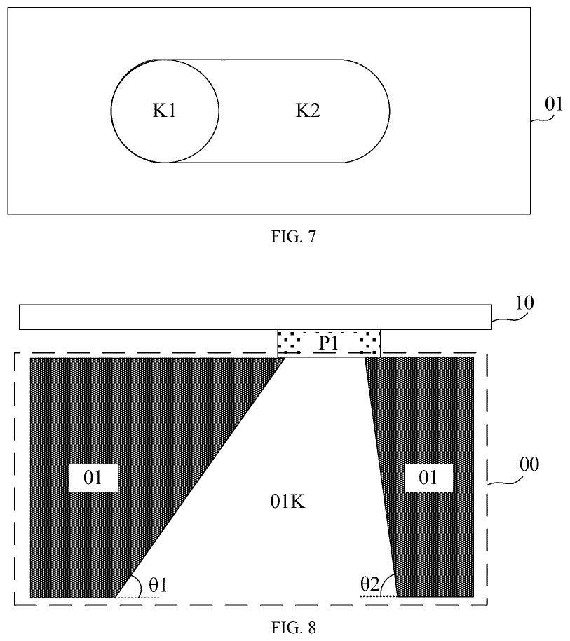

In some embodiments, taking one evaporation through-hole 01K as an example, FIG. 4 further shows an equivalent structural diagram of the evaporation mask shown in FIG. 3. FIG. 5 further shows an equivalent cross-sectional view of the evaporation mask shown in FIG. 3. FIG. 6 further shows an equivalent top view of the evaporation mask shown in FIG. 3. FIG. 7 further shows an equivalent bottom view of the evaporation mask shown in FIG. 4. It should be noted that, referring to FIG. 4, the top view angle of the equivalent top view is a view angle viewed downward from the side of the evaporation mask 00 proximal to the to-be-evaporated substrate 10. The bottom view angle of the equivalent bottom view is a view angle viewed upward from the side of the evaporation mask 00 distal to the to-be-evaporated substrate 10. The bottom view and the top view involved in the following embodiments are the same and are not repeated herein. In addition, an upper opening K1 and a lower opening K2 are further identified in FIGS. 4, 6 and 7, respectively. As can also be seen from FIGS. 4-7, the aperture of the upper opening K1 of the evaporation through-hole 01K on the side close to the to-be-evaporated substrate 10 is much less than the aperture of the lower opening K1 of the evaporation through-hole 01K on the side distal to the to-be-evaporated substrate 10.

For example, referring to FIG. 8, the evaporation through-hole 01K shown includes two through-hole angles θ1 and θ2, each of which is an acute angle.

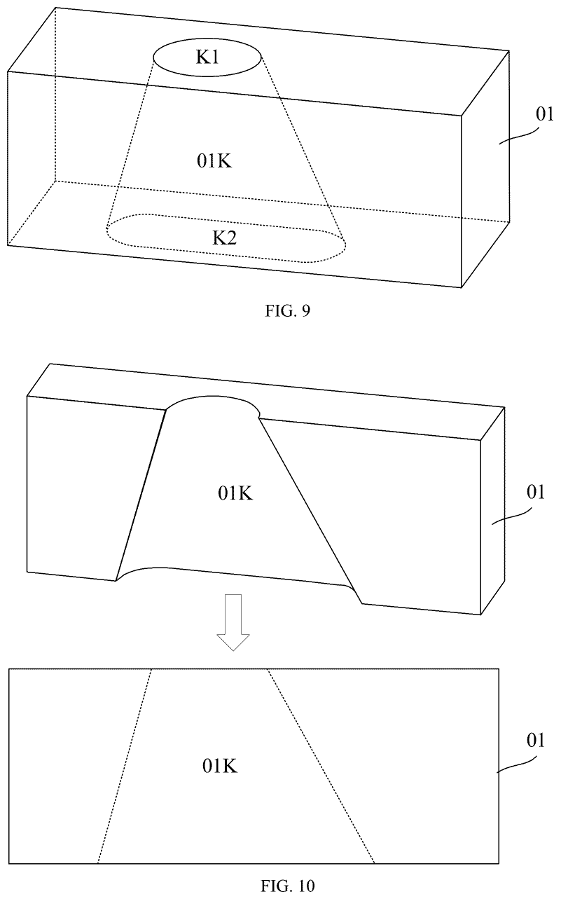

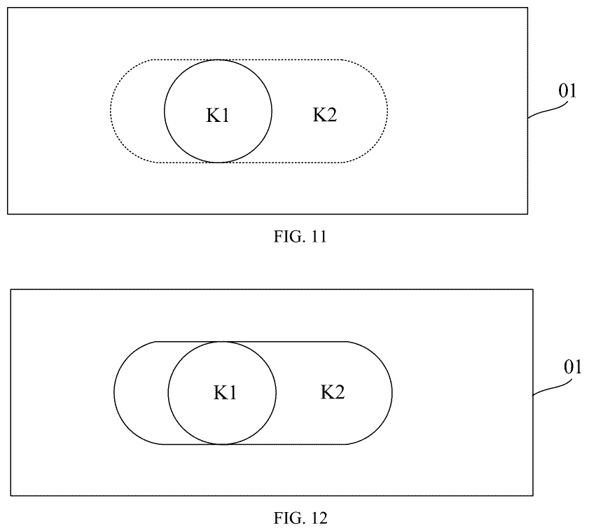

In some embodiments, FIG. 9 further shows an equivalent structural view of the evaporation mask shown in FIG. 8. FIG. 10 further shows an equivalent cross-sectional view of the evaporation mask 00 shown in FIG. 8. FIG. 11 further shows an equivalent top view of the evaporation mask 00 shown in FIG. 8. FIG. 12 further shows an equivalent bottom view of the evaporation mask 00 shown in FIG. 8. In addition, an upper opening K1 and a lower opening K2 are further identified in FIGS. 9, 11 and 12, respectively.

In some embodiments, in the two through-hole angles θ1 and θ2 of the evaporation through-hole 01K, the smallest through-hole angle (e.g., the through-hole angle θ1 described in the above embodiments) is greater than or equal to an arc tangent value of a ratio of the thickness d of the mask plate 01 to a first aperture r1 and is less than or equal to an arc tangent value of a ratio of the thickness d of the mask plate 01 to a second aperture r2. Namely, arctan (d/r2)≥θ1≥arctan(d/r1).

In addition, referring to FIGS. 2 and 3, the first aperture r1 is an aperture of the opening (i.e., the lower opening) of the evaporation through-hole 01K on the side distal to the to-be-evaporated substrate 10 in the case that the opening of the evaporation through-hole 01K on the side distal to the to-be-evaporated substrate 10 extends to one adjacent sub-pixel region A1. The second aperture r2 is an aperture of the opening of the evaporation through-hole 01K on the side distal to the to-be-evaporated substrate 10 in the case that the opening of the evaporation through-hole 01K on the side distal to the to-be-evaporated substrate 10 extends to two or more adjacent sub-pixel regions. That is, the smallest through-hole angle θ1 is associated with the aperture of the opening of the evaporation through-hole 01K on the side distal to the to-be-evaporated substrate 10, while the aperture of the opening of the evaporation through-hole 01K on the side distal to the to-be-evaporated substrate 10 is associated with the number of sub-pixel regions A1 to which the opening of the evaporation through-hole 01K on the side distal to the to-be-evaporated substrate 10 extends.

As an alternative implementation, as can be seen from FIGS. 2, 3 and 8, the evaporation through-hole 01K described in the embodiments of the present disclosure is trumpet-shaped along a direction perpendicular to the to-be-evaporated substrate 10, and the evaporation through-hole 01K is also referred to as a trumpet-shaped through-hole.

In combination with the embodiments that the aperture of the upper opening is less than that of the lower opening, the trumpet shape in the embodiments of the present disclosure is a shape in which the aperture of the evaporation through-hole 01K gradually decreases along a direction approaching the to-be-evaporated substrate 10. The small open end (i.e., the upper opening close to the to-be-evaporated substrate 10) of the trumpet-shaped through-hole closes to the to-be-evaporated substrate 10, and after the evaporation mask 00 is aligned with the to-be-evaporated substrate 10, the small open end is in coincidence with the position of the corresponding sub-pixel region A1 (i.e., overlapped with each other).

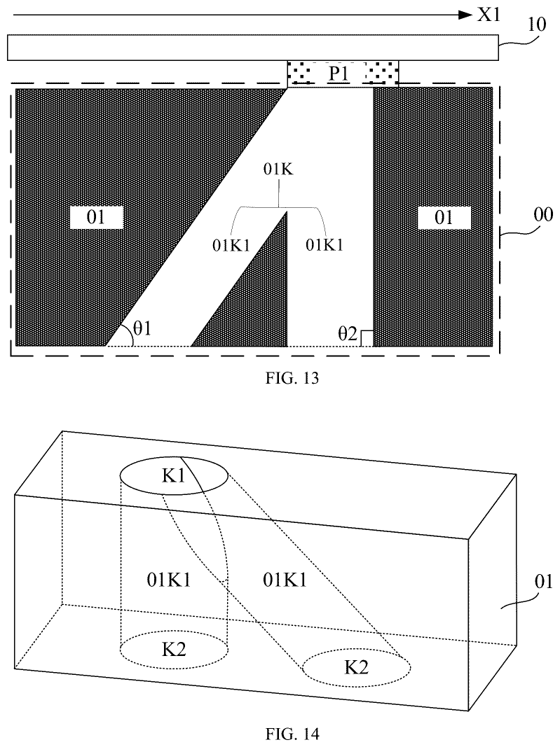

As another alternative implementation, referring to yet another evaporation mask shown in FIG. 13, the evaporation through-hole 01K described in the embodiments of the present disclosure includes a plurality of sub-through-holes 01K1 formed at intervals in a direction X1 parallel to the to-be-evaporated substrate 10.

In addition, the openings (i.e., the upper openings) of the plurality of sub-through-holes 01K1 on the sides proximal to the to-be-evaporated substrate 10 are overlapped (may also be considered as communicating with each other), and the openings (i.e., the lower openings) of each two adjacent sub-through-holes 01K1 on the sides distal to the to-be-evaporated substrate 10 are spaced apart by the mask plate 01. That is, the opening positions of the plurality of sub-through-holes 01K1 on the sides proximal to the to-be-evaporated substrate 10 are the same, and after the evaporation mask 00 is aligned with the to-be-evaporated substrate 10, the position of communicating with each other is in coincidence with the position of the corresponding sub-pixel region A1 (i.e., overlapped with each other).

In some embodiments, in a scenario where a plurality of evaporation sources evaporate different materials to achieve co-doping, a plurality of sub-through-holes 01K1 of the evaporation through-hole 01K correspond to the plurality of evaporation sources one by one. Each evaporation source is configured to evaporate the material onto the to-be-evaporated substrate 10 through a corresponding sub-through-hole 01K1.

In some embodiments, in the plurality of sub-through-holes 01K1, each sub-through-hole 01K1 includes two opposite through-hole angles in a direction parallel to the to-be-evaporated substrate 10. In addition, the two through-hole angles of the sub-through-hole 01K1 are equal, and the through-hole angles of the respective sub-through-holes 01K1 are unequal. That is, the apertures of each sub-through-hole 01K1 are the same.

For example, referring to FIG. 13, the evaporation through-hole 01K shown includes two sub-through-holes 01K1. In this application scenario, the through-hole angles of the two sub-through-holes 01K1 are the through-hole angles θ1 and θ2 as identified in FIGS. 2, 3, and 8, respectively.

In addition, as can be seen from the above embodiments, in the two sub-through-holes 01K1, two through-hole angles of one sub-through-hole 01K1 are both acute angles while two through-hole angles of the other sub-through-hole 01K1 are both right angles, corresponding to the embodiments shown in FIGS. 2 and 3. Or, in the two sub-through-holes 01K1, two through-hole angles of each sub-through-hole 01K1 are both acute angles, corresponding to the embodiments shown in FIG. 8.

For example, the evaporation mask shown in FIG. 13 includes two sub-through-holes 01K1, two through-hole angles (i.e., θ1) of one sub-through-hole 01K1 being both acute angles, and two through-hole angles (i.e., θ2) of the other sub-through-hole 01K1 being both right angles.

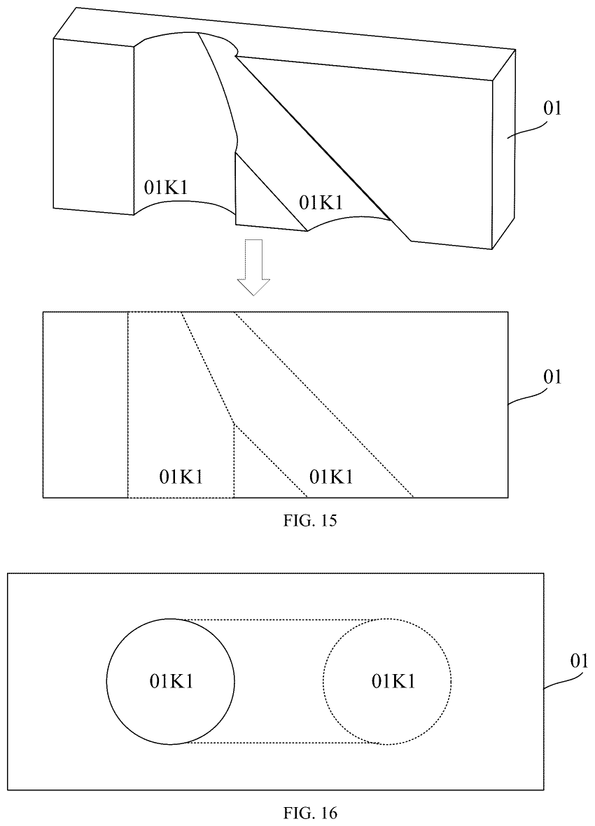

In some embodiments, FIG. 14 further shows an equivalent structural view of the evaporation mask shown in FIG. 13. FIG. 15 further shows an equivalent cross-sectional view of the evaporation mask shown in FIG. 13. FIG. 16 further shows an equivalent top view of the evaporation mask 00 in the evaporation device shown in FIG. 13. FIG. 17 further shows an equivalent bottom view of the evaporation mask shown in FIG. 13. In addition, an upper opening K1 and a lower opening K2 are further identified in FIGS. 14, 16, and 17, respectively, and as can be seen from FIGS. 14-17, the evaporation through-hole 01K includes two sub-through-holes 01K1, and the upper openings K1 of the two sub-through-holes 01K1 are in coincidence with each other, and the lower openings K2 of the two sub-through-holes 01K1 are spaced by the mask plate 01. That is, one sub-through-hole 01K1 is an inclined hole, and the other sub-through-hole 01K1 is a straight hole. Accordingly, the portion of the evaporation mask 00 spacing the two sub-through-holes 01K1 is in the form of a right-angled triangle as shown in FIG. 13.

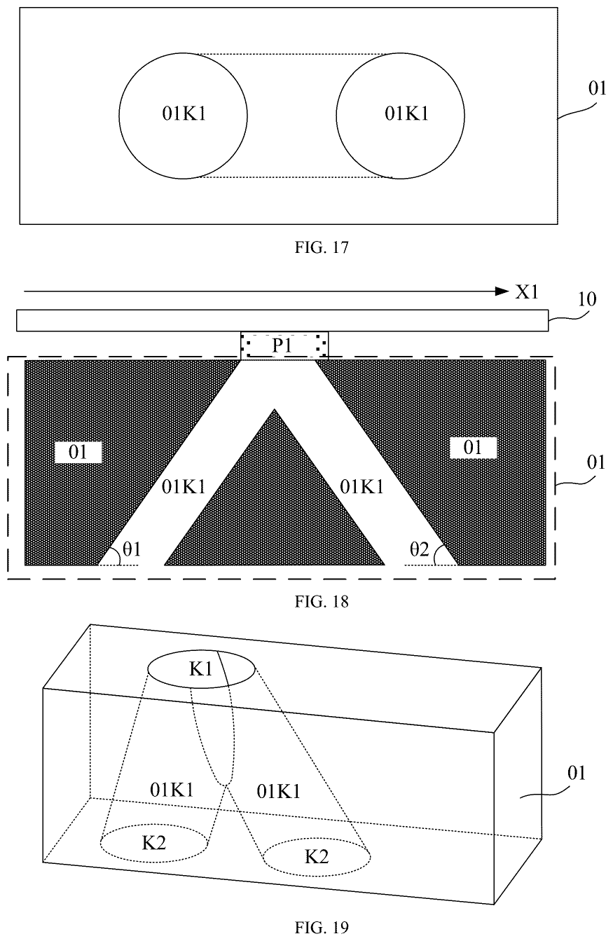

For example, in the evaporation mask shown in FIG. 18, two through-hole angles (i.e., θ1 and θ2) corresponding to each sub-through-hole 01K1 are both acute angles.

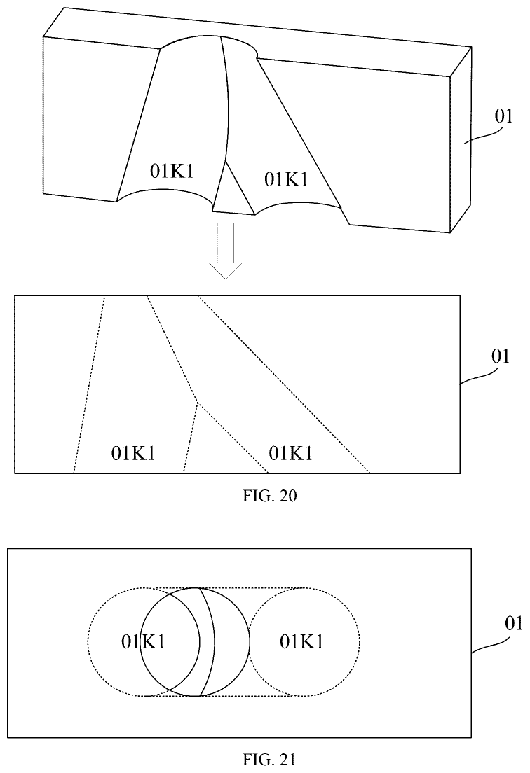

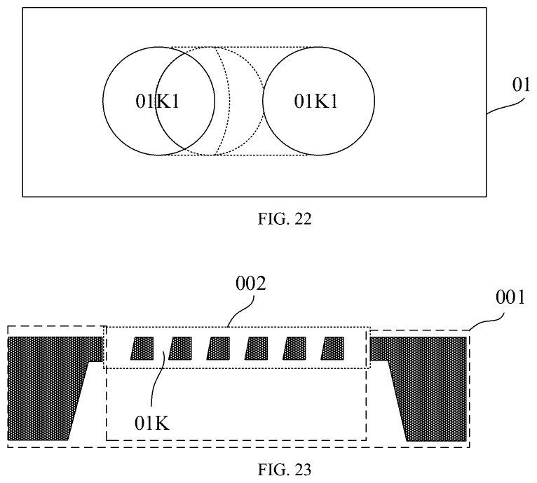

In some embodiments, FIG. 19 further shows an equivalent structural view of the evaporation mask shown in FIG. 18. FIG. 20 further shows an equivalent cross-sectional view of the evaporation mask shown in FIG. 18. FIG. 21 further shows an equivalent top view of the evaporation mask shown in FIG. 18. FIG. 22 further shows an equivalent bottom view of the evaporation mask shown in FIG. 19. In addition, FIG. 19 further schematically identifies an upper opening K1 and a lower opening K2. That is, the two sub-through-holes 01K1 are both inclined holes. Accordingly, the portion of the evaporation mask 00 spacing the two sub-through-holes 01K1 is in the form of a non-right-angled triangle as shown in FIG. 18.

In some embodiments, in the embodiments of the present disclosure, an orthographic projection of the opening (i.e., the upper opening K1) of the evaporation through-hole 01K on the side proximal to the to-be-evaporated substrate 10 on the to-be-evaporated substrate 10 is circular as shown in the figure, or is elliptical or rectangular in some other embodiments. The orthographic projection of the opening (i.e., the upper opening K1) of the evaporation through-hole 01K on the side distal to the to-be-evaporated substrate 10 on the to-be-evaporated substrate 10 is elliptical as shown in the figure. Or in some other embodiments, the orthographic projection is rectangular.

In the case that the opening of the evaporation through-hole 01K is set to be elliptical, sub-pixels can be formed by evaporation at more positions on the to-be-evaporated substrate 10, thus ensuring the high resolution of the manufactured display panel.

In some embodiments, referring to FIG. 23, in the embodiments of the present disclosure, the mask plate 00 includes: a frame portion 001 and an opening portion 002. The frame portion 001 is configured to define the opening portion 002, and the opening portion 002 is configured to form the plurality of evaporation through-holes 01K described in the above embodiments.

The through-hole angle of the evaporation through-hole 01K is less than an angle a1 between the frame portion 001 and the to-be-evaporated substrate 10. Therefore, the thickness of the opening portion 002 is smaller than the thickness of the frame portion 001, such that sagging of the opening portion 002 can be avoided, and it can be ensured that different evaporation sources reliably evaporate materials onto the to-be-evaporated substrate 10 through the evaporation through-holes 01K, thereby avoiding material layering and ensuring a good co-doping effect.

In some embodiments of the present disclosure, the frame portion 001 is made of single crystal silicon (SCS). The opening portion 002 is made of at least one of single crystal silicon (SCS), silicon oxide (SiOx), and silicon nitride (SiNx), i.e., including one or a combination of more of single crystal silicon (SCS), silicon oxide (SiOx), and silicon nitride (SiNx).

For example, both the frame portion 001 and the opening portion 002 are made of single crystal silicon (SCS).

For another example, the frame portion 001 is made of single crystal silicon (SCS), and the single crystal silicon (SCS) is inlaid with a material of silicon oxide (SiOx). The opening portion 002 is made of single crystal silicon (SCS).

For still another example, the frame portion 001 is made of single crystal silicon (SCS), and the opening portion 002 is made of silicon oxide (SiOx).

In summary, the embodiments of the present disclosure provide an evaporation mask. The evaporation mask includes a mask plate, and a plurality of evaporation through-holes penetrating through the mask plate. The plurality of evaporation through-holes correspond to a plurality of sub-pixel regions spaced apart from each other on a to-be-evaporated substrate one by one such that a plurality of sub-pixels of different colors are formed by an evaporation source evaporating in the plurality of sub-pixel regions. As an opening of each evaporation through-hole on the side proximal to the to-be-evaporated substrate has a smaller aperture than an opening of the evaporation through-hole on the side distal to the to-be-evaporated substrate, and can extend to at least one adjacent sub-pixel region with formed sub-pixels of different colors, the through-hole angles of the evaporation through-holes are flexibly set, and the evaporation angles of the evaporation sources are adjusted accordingly, such that a plurality of evaporation sources reliably evaporate different materials onto the to-be-evaporated substrate, and the different evaporated materials can be reliably co-doped, thereby providing a good evaporation effect.

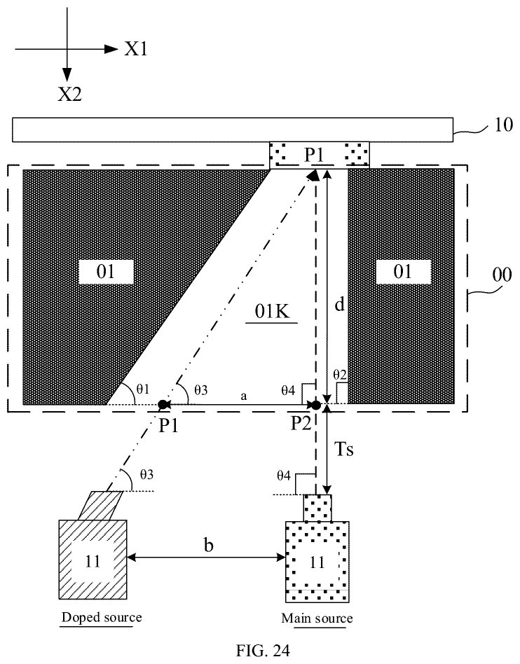

FIG. 24 is a schematic structural diagram of an evaporation device according to some embodiments of the present disclosure. As shown in FIG. 24, the evaporation device includes a plurality of evaporation sources 11, and the evaporation mask 00 shown in any one of FIGS. 2-23.

The plurality of evaporation sources 11 are disposed on the side of the evaporation mask 00 distal to the to-be-evaporated substrate 10, and the plurality of evaporation sources 11 are arranged at intervals along a direction X1 parallel to the to-be-evaporated substrate 10.

A nozzle of the evaporation source 11 faces the evaporation mask 00, the evaporation source 11 is configured to evaporate a material onto a sub-pixel region A1 of the to-be-evaporated substrate 10 through the evaporation through-hole 01K in the evaporation mask 00 so as to form a sub-pixel P1, and materials evaporated by the respective evaporation sources 11 are different. Therefore, co-doping of materials is achieved to acquire a required functional film layer with co-doped materials, such as a light-emitting layer.

For example, FIG. 24 schematically shows only two evaporation sources 11, and as can be seen from the above embodiments, in the two evaporation sources 11, one evaporation source 11 is a main source, and the other evaporation source 11 is a doped source.

In addition, an evaporation included angle is formed between the nozzle of the evaporation source 11 and the to-be-evaporated substrate 10, which is also referred to as an evaporation angle. In FIG. 24, for the two evaporation sources 11, an evaporation angle of the doped source is identified as 03, and an evaporation angle of the main source is identified as θ4. A difference value between the evaporation angle and the through-hole angle of the evaporation through-hole 01K corresponding to the evaporation angle is less than a difference threshold. In some embodiments, the difference threshold is small, generally between 0 and 0.5. Therefore, the difference between the evaporation angle and the through-hole angle is small and tends to be close to or just equal.

It should be noted that, the case where the difference value between the evaporation angle and the through-hole angle of the evaporation through-hole 01K corresponding to the evaporation angle is less than the difference threshold means that: for each through-hole angle, the difference value between the evaporation angle of the evaporation source closest to the through-hole angle and the through-hole angle of the evaporation through-hole 01K is less than the difference threshold.

Research shows that by setting of the structure and the angles of the evaporation through-hole 01K that meet the record of the above embodiments, different materials evaporated by a plurality of evaporation sources 11 can be reliably doped onto the to-be-evaporated substrate 10, and the materials evaporated along a specific evaporation angle can be evaporated to the corresponding regions, thereby avoiding evaporation to other positions such as the inner walls of the evaporation through-hole 01K, and ensuring that the evaporation sources 11 can reliably evaporate the materials onto the to-be-evaporated substrate 10.

In summary, the embodiments of the present disclosure provide an evaporation device. The evaporation device includes an evaporation mask and a plurality of evaporation sources. The evaporation mask includes a mask plate, and a plurality of evaporation through-holes penetrating through the mask plate. The plurality of evaporation sources are configured to evaporate different materials onto a to-be-evaporated substrate through the evaporation through-holes, thereby achieving co-doping of the materials. As an opening of the evaporation through-hole on the side proximal to the to-be-evaporated substrate has a smaller aperture than an opening of the evaporation through-hole on the side distal to the to-be-evaporated substrate, and can extend to at least one adjacent sub-pixel region with formed sub-pixels of different colors, the through-hole angles of the evaporation through-holes are flexibly set, and the evaporation angles of the evaporation sources are adjusted accordingly, such that a plurality of evaporation sources reliably evaporate different materials onto the to-be-evaporated substrate, and the different evaporated materials can be reliably co-doped, thereby providing a good evaporation effect.

In some embodiments, referring to FIG. 24, in the embodiments of the present disclosure, the evaporation device includes two evaporation sources 11, and in a direction parallel to the to-be-evaporated substrate 10, the evaporation through-hole 01K includes two opposite through-hole angles θ1 and θ2. On this basis, the evaporation angle of each evaporation source 11 is equal to the through-hole angle closer to the evaporation source in the two through-hole angles of the evaporation through-hole 01K. For example, referring to FIG. 24, the evaporation angle θ3 of the doped source and the through-hole angle θ1 closest thereto are exactly equal, and the evaporation angle θ4 of the main source and the through-hole angle θ2 closest thereto are exactly equal. That is, the difference threshold described in the above embodiments is 0, and the difference value between the evaporation angle and the through-hole angle of the evaporation through-hole 01K is equal to the difference threshold, that is, equal to 0.

Therefore, it can be considered that the nozzle direction of the evaporation source 11 is parallel to the inner wall of the evaporation through-hole 01K closest to the evaporation source, that is, the evaporation direction is the same as the extending direction of the corresponding inner wall, which is also referred to as matching. In this way, it can be further ensured that each evaporation source 11 reliably evaporates a material onto the to-be-evaporated substrate 10 through the evaporation through-hole 01K, and the material will not be formed at other positions (such as inner walls).

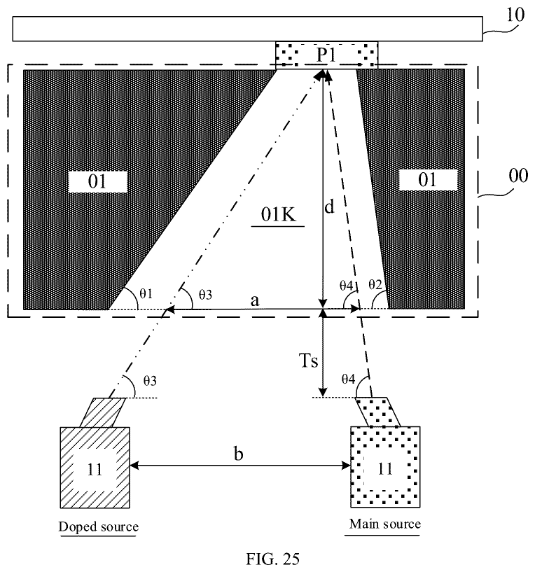

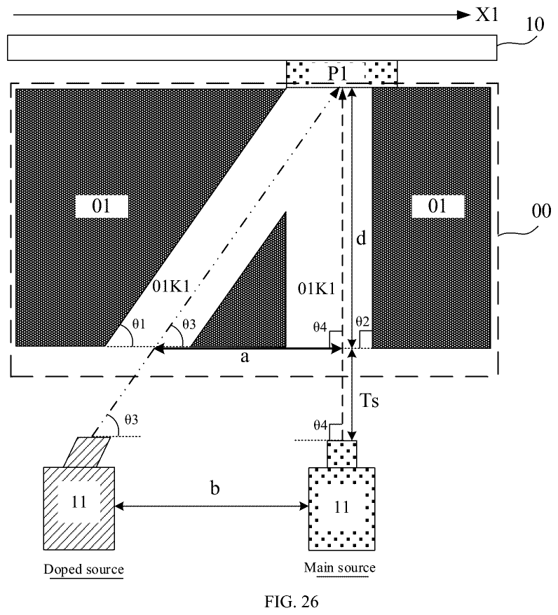

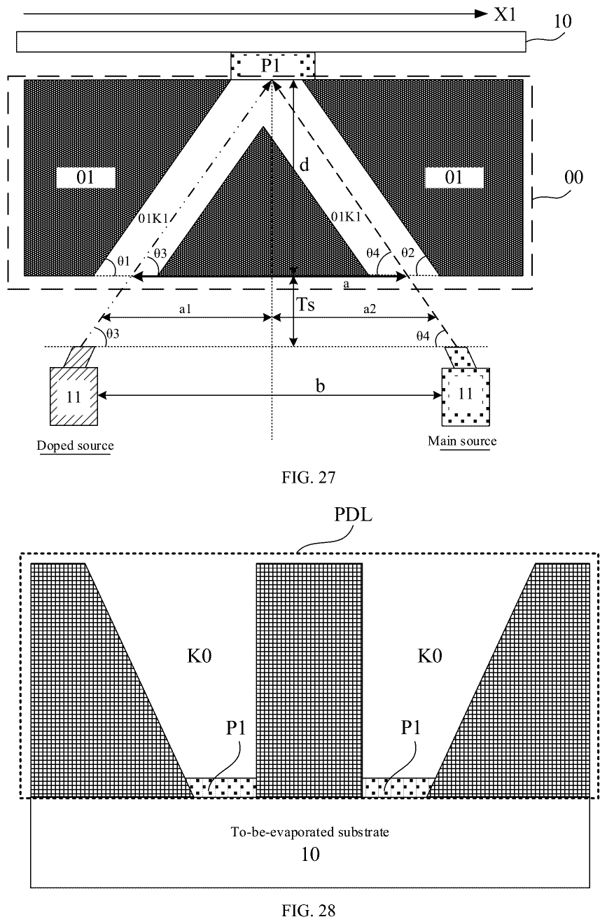

In some embodiments, FIG. 24 is a schematic structural diagram of an evaporation device including evaporation sources, which is exemplified by the structures shown in FIGS. 2 and 3. FIG. 25 is a schematic structural diagram of another evaporation device including evaporation sources, which is exemplified by the structure shown in FIG. 8. FIG. 26 is a schematic structural diagram of still another evaporation device including evaporation sources, which is exemplified by the structure shown in FIG. 13. FIG. 27 is a schematic structural diagram of yet another evaporation device including evaporation sources, which is exemplified by the structure shown in FIG. 18. In FIGS. 25 and 27, the nozzles of the two evaporation sources 11 are close to each other.

In the structures shown in FIGS. 24 and 25, that is, on the basis that the cross-section of the evaporation through-hole 01K is trumpet-shaped along a direction X2 perpendicular to the to-be-evaporated substrate 10, the distance b between each two adjacent evaporation sources 11 is negatively correlated with the smallest through-hole angle (e.g., θ1) of the two through-hole angles of the evaporation through-hole 01K. That is, the larger the through-hole angle θ1 is, the smaller the distance b is; and the smaller the through-hole angle θ1 is, the larger the distance b is. The smallest through-hole angle θ1 corresponds to an inner wall with the largest inclination degree, so it can be considered that the largest inclination angle of the evaporation through-hole 01K is negatively correlated with the distance b. On this basis, after the evaporation mask 00 is manufactured, the distance b between each two adjacent evaporation sources 11 may be flexibly adjusted based on the through-hole angle θ1 of the evaporation mask 00.

In addition, referring to the structures shown in FIGS. 24-27, the distance b between each two adjacent evaporation sources 11 is negatively correlated with a first parameter and is positively correlated with a second parameter. That is, the larger the first parameter is, the smaller the distance b is, and the smaller the first parameter is, the larger the distance b is; and the larger the second parameter is, the larger the distance b is, and the smaller the second parameter is, the smaller the distance b is.

Referring to FIGS. 24-27, the first parameter is the thickness d of the mask plate 01 of the evaporation mask 00, and the thickness direction is a direction X2 perpendicular to the to-be-evaporated substrate 10. The second parameter is a product of the first sub-parameter and the second sub-parameter.

The first sub-parameter is, for each two adjacent evaporation sources 11, a distance a between an intersection P1 of a nozzle extension line of one evaporation source 11 and one side of the evaporation through-hole 01K distal to the to-be-evaporated substrate 10 and an intersection P2 of a nozzle extension line of the other evaporation source 11 and one side of the evaporation through-hole 01K distal to the to-be-evaporated substrate 10. The intersections P1 and P2 are only schematically identified in FIG. 24. For the structures shown in FIGS. 26 and 27, the distance a is considered as the distance between the centers of the lower openings of the two sub-through-holes 01K1. FIG. 27 further schematically identifies the distance between the center of the lower opening of each sub-through-hole 01K1 and the center of the lower opening K2 of the evaporation through-hole 01K, i.e., a1 and a2, respectively. The second sub-parameter is the sum of the first parameter (i.e., the thickness d of the mask plate 01) and a vertical distance Ts between the plurality of evaporation sources 11 and the evaporation mask 00.

For example, the distance b between each two adjacent evaporation sources 11 satisfies: b=a(d+Ts)/d.

As can be seen from the above embodiments, d is the first parameter, a is the first sub-parameter, and Ts is the vertical distance between the plurality of evaporation sources 11 and the evaporation mask 00. For example, Ts is 600 millimeters (mm), d is 20 μm, a is 4 μm, and thus b is 120 as calculated.

In addition, for the structures shown in FIGS. 24 and 26, the acute through-hole angle θ1=arctan(d/a). For the structure shown in FIG. 27, in the two acute through-hole angles θ1 and θ2, one through-hole angle θ1=arctan (d/a1), and the other through-hole angle θ2=arctan(d/a2).

That is, as can be seen from the above embodiments, in the embodiments of the present disclosure, in an aspect, a trumpet-shaped evaporation through-hole 01K are designed on the evaporation mask 00 to match with an evaporation angle of the evaporation source 11, so as to achieve reliable co-doping of different evaporated materials. In another aspect, a sub-through-hole 01K1 with the same angle as the evaporation angle of the evaporation source 11 is designed on the evaporation mask 00, so as to achieve reliable co-doping of different evaporated materials.

In addition, in some embodiments, the original film layer of the display panel can be directly reused to replace the evaporation mask 00, thereby saving the cost. For example, referring to FIG. 28, the display panel according to the embodiments of the present disclosure further includes: a pixel definition layer (PDL) disposed on one side of the to-be-evaporated substrate 10.

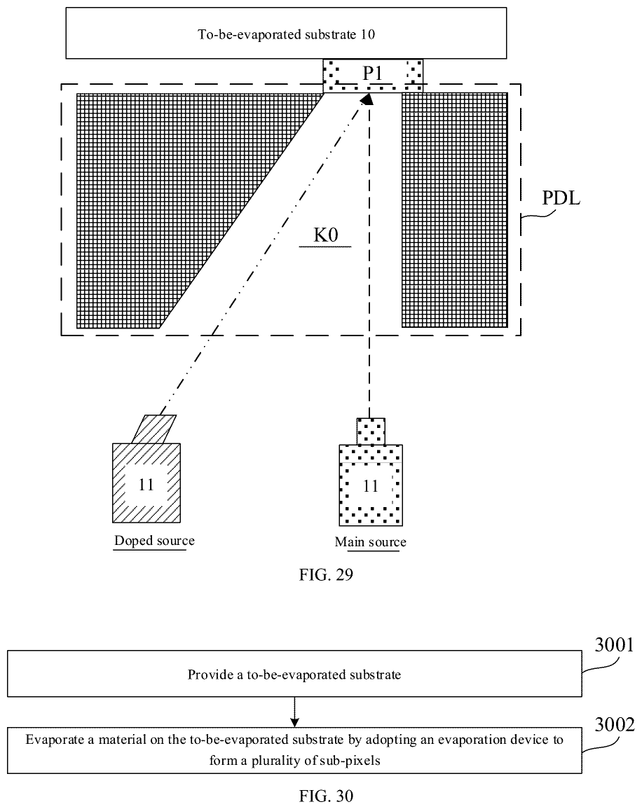

The pixel definition layer (PDL) is provided with a plurality of openings K0 and is configured to define different sub-pixels P1 of the display panel in different openings K0, and the evaporation mask 00 reuses the pixel definition layer (PDL). That is, the pixel definition layer (PDL) is provided with the openings K0 same as the evaporation through-hole 01K shown in FIGS. 24-27. The same part herein means that: the structure and the mask inclination angle are the same. In the evaporation process, the pixel definition layer (PDL) is directly used as the evaporation mask 00 and performs evaporation together with the evaporation sources 11. For example, FIG. 29 is a schematic structural diagram of an evaporation device with reusing a pixel definition layer (PDL) as an evaporation mask 00, which is exemplified by the structure shown in FIG. 24.

In summary, the embodiments of the present disclosure provide an evaporation device. The evaporation device includes an evaporation mask and a plurality of evaporation sources. The evaporation mask includes a mask plate, and a plurality of evaporation through-holes penetrating through the mask plate. The plurality of evaporation sources are configured to evaporate different materials onto a to-be-evaporated substrate through the evaporation through-holes, thereby achieving co-doping of the materials. As an opening on one side of each evaporation through-hole close to the to-be-evaporated substrate has a smaller aperture than an opening on one side of the evaporation through-hole distal to the to-be-evaporated substrate, and can extend to at least one adjacent sub-pixel region with formed sub-pixels of different colors, the through-hole angles of the evaporation through-holes are flexibly set, and the evaporation angles of the evaporation sources are adjusted accordingly, such that a plurality of evaporation sources reliably evaporate different materials onto the to-be-evaporated substrate, and the different evaporated materials can be reliably co-doped, thereby providing a good evaporation effect.

FIG. 30 is a flowchart of an evaporation method according to some embodiments of the present disclosure. As shown in FIG. 30, the method includes:

S3001, providing a to-be-evaporated substrate; and

S3002, by adopting an evaporation device, evaporating a material on the to-be-evaporated substrate to form a plurality of sub-pixels.

In the steps, the evaporation device adopted is the evaporation device shown in any one of FIGS. 24-27.

In summary, the embodiments of the present disclosure provide an evaporation method. The method adopts an evaporation device to simultaneously evaporate different materials on a to-be-evaporated substrate to form a plurality of sub-pixels. The evaporation device includes an evaporation mask and a plurality of evaporation sources. The evaporation mask includes a mask plate, and a plurality of evaporation through-holes penetrating through the mask plate. The plurality of evaporation sources are configured to evaporate different materials onto a to-be-evaporated substrate through the evaporation through-holes, thereby achieving co-doping of the materials. As an opening of the evaporation through-hole on the side proximal to the to-be-evaporated substrate has a smaller aperture than an opening of the evaporation through-hole on the side distal to the to-be-evaporated substrate, and can extend to at least one adjacent sub-pixel region with formed sub-pixels of different colors, the through-hole angles of the evaporation through-holes are flexibly set, and the evaporation angles of the evaporation sources are adjusted accordingly, such that a plurality of evaporation sources reliably evaporate different materials onto the to-be-evaporated substrate, and the different evaporated materials can be reliably co-doped, thereby providing a good evaporation effect.

It should be noted that, in the accompanying drawings, the dimensions of the layers and regions may be exaggerated for clarity of illustration. Also, it should be understood that, in the case that an element or layer is referred to as being “on” another element or layer, it may be directly on the other element, or an intermediate layer may be present. In addition, it should be understood that, in the case that an element or layer is referred to as being “under” another element or layer, it may be directly under the other element, or one or more intermediate layers or elements may be present. In addition, it can also be understood that, in a case that a layer or element is referred to as being “between” two layers or elements, it may be the only layer between the two layers or elements, or one or more intermediate layers or elements may also be present. Like reference numerals refer to like elements throughout the present disclosure.

In addition, terms used in detailed description of the present disclosure are defined to merely explain the embodiments of the present disclosure and are not intended to limit the present disclosure. Unless otherwise defined, technical or scientific terms used in detailed description of the present disclosure should have the ordinary meanings as understood by those of ordinary skill in the art to which the present disclosure belongs.

For example, in the embodiments of the present disclosure, the terms “first” and “second” are used for descriptive purposes only and should not be construed as indicating or implying the relative importance. The term “a plurality of” refers to two or more, unless otherwise explicitly defined.

Likewise, the terms “a”, “an” or other similar words do not indicate a limitation of quantity, but rather the presence of at least one.

The terms “include”, “comprise” or other similar words indicate that the elements or objects stated before “include” or “comprise” encompass the elements or objects and equivalents thereof listed after “include” or “comprise”, but do not exclude other elements or objects.

“Up”, “down”, “left”, “right” or the like is only defined to indicate relative position relationship. In a case that the absolute position of the described object is changed, the relative position relationship may be changed accordingly.

Described above are merely optional embodiments of the present disclosure and are not intended to limit the present disclosure. Any modifications, equivalents, improvements, and the like, made within the spirit and principle of the present disclosure, should be included in the protection scope of the present disclosure.

1. An evaporation mask, applicable to a side of a to-be-evaporated substrate provided with a plurality of sub-pixel regions spaced apart from each other, wherein the evaporation mask comprises:
a mask plate; and
a plurality of evaporation through-holes penetrating through the mask plate, the plurality of evaporation through-holes corresponding to the plurality of sub-pixel regions one by one such that a plurality of sub-pixels of different colors are formed by an evaporation source evaporating in the plurality of sub-pixel regions; and
wherein for each of the evaporation through-holes, an aperture of an opening of the evaporation through-hole on a side proximal to the to-be-evaporated substrate is less than an aperture of an opening of the evaporation through-hole on a side distal to the to-be-evaporated substrate, the opening of the evaporation through-hole on the side distal to the to-be-evaporated substrate extends to at least one adjacent sub-pixel region, and a color of a sub-pixel evaporated in a sub-pixel region corresponding to the evaporation through-hole is different from a color of a sub-pixel evaporated in the at least one adjacent sub-pixel region.

2. The evaporation mask according to claim 1, wherein the plurality of sub-pixel regions are arranged in an array, and a plurality of sub-pixels evaporated in the plurality of sub-pixel regions comprise a plurality of sub-pixels of three colors, and the sub-pixels are sequentially arranged in an order of every three sub-pixels of different colors in a row direction; and the opening of each evaporation through-hole on the side distal to the to-be-evaporated substrate extends to two adjacent sub-pixel regions.

3. The evaporation mask according to claim 1, wherein a distance between openings of each two adjacent evaporation through-holes on the side distal to the to-be-evaporated substrate is greater than a distance between two sub-pixels formed in two sub-pixel regions corresponding to the two adjacent evaporation through-holes.

4. The evaporation mask according to claim 1, wherein the evaporation through-hole comprises two through-hole angles disposed oppositely in a direction parallel to the to-be-evaporated substrate; and
the two through-hole angles of the evaporation through-hole are unequal, and in the two through-hole angles of the evaporation through-hole, a through-hole angle proximal to an upstream direction in which the evaporation source moves is less than a through-hole angle distal to the upstream direction in which the evaporation source moves.

5. The evaporation mask according to claim 4, wherein in the two through-hole angles of the evaporation through-hole, one through-hole angle is a right angle, and another through-hole angle is an acute angle; or
both the two through-hole angles of the evaporation through-hole are acute angles.

6. The evaporation mask according to claim 5, wherein in the two through-hole angles of the evaporation through-hole, a smallest through-hole angle is greater than or equal to an arc tangent value of a ratio of a thickness of the mask plate to a first aperture, and is less than or equal to an arc tangent value of a ratio of the thickness of the mask plate to a second aperture;
wherein the first aperture is an aperture of the opening of the evaporation through-hole on the side distal to the to-be-evaporated substrate in a case that the opening of the evaporation through-hole on the side distal to the to-be-evaporated substrate extends to one adjacent sub-pixel region; and the second aperture is an aperture of the opening of the evaporation through-hole on the side distal to the to-be-evaporated substrate in a case that the opening of the evaporation through-hole on the side distal to the to-be-evaporated substrate extends to each of two or more adjacent sub-pixel regions.

7. The evaporation mask according to claim 1, wherein a cross-section of the evaporation through-hole is trumpet-shaped in a direction perpendicular to the to-be-evaporated substrate.

8. The evaporation mask according to claim 1, wherein the evaporation through-hole comprises a plurality of sub-through-holes spaced apart from each other along a direction parallel to the to-be-evaporated substrate; and
wherein openings of the plurality of sub-through-holes on the side proximal to the to-be-evaporated substrate are overlapped with each other, and openings of each two adjacent sub-through-holes on the side distal to the to-be-evaporated substrate are spaced apart by the mask plate.

9. The evaporation mask according to claim 8, wherein each of the sub-through-holes comprises two through-hole angles disposed oppositely in the direction parallel to the to-be-evaporated substrate, and the two through-hole angles corresponding to each sub-through-hole are equal, and the through-hole angles corresponding to respective sub-through-holes are unequal.

10. The evaporation mask according to claim 9, wherein the evaporation through-hole comprises two sub-through-holes;
both two through-hole angles corresponding to one of the two sub-through-holes are acute angles, and both two through-hole angles corresponding to another of the two sub-through-holes are right angles; or
both two through-hole angles corresponding to each of the two sub-through-holes are acute angles.

11. The evaporation mask according to claim 1, wherein an orthographic projection of the opening of the evaporation through-hole on the side proximal to the to-be-evaporated substrate is circular, elliptical, or rectangular; and an orthographic projection of the opening of the evaporation through-hole on the side distal to the to-be-evaporated substrate is elliptical or rectangular.

12. The evaporation mask according to claim 1, wherein a ratio of a thickness of the mask plate to the aperture of the opening of the evaporation through-hole on the side distal to the to-be-evaporated substrate is greater than or equal to 2.

13. The evaporation mask according to claim 1, wherein the mask plate comprises a frame portion and an opening portion, the frame portion being configured to define the opening portion, and the opening portion being configured to form the plurality of evaporation through-holes; and
wherein a through-hole angle of the evaporation through-hole is less than an angle between the frame portion and the to-be-evaporated substrate.

14. The evaporation mask according to claim 13, wherein the frame portion is made of single crystal silicon, and the opening portion is made of at least one of single crystal silicon, silicon oxide, or silicon nitride.

15. An evaporation device, comprising a plurality of evaporation sources and an evaporation mask; wherein
the evaporation mask is applicable to a side of a to-be-evaporated substrate provided with a plurality of sub-pixel regions spaced apart from each other, wherein the evaporation mask comprises: a mask plate; and a plurality of evaporation through-holes penetrating through the mask plate, the plurality of evaporation through-holes corresponding to the plurality of sub-pixel regions one by one such that a plurality of sub-pixels of different colors are formed by an evaporation source evaporating in the plurality of sub-pixel regions; and wherein for each of the evaporation through-holes, an aperture of an opening of the evaporation through-hole on a side proximal to the to-be-evaporated substrate is less than an aperture of an opening of the evaporation through-hole on a side distal to the to-be-evaporated substrate, the opening of the evaporation through-hole on the side distal to the to-be-evaporated substrate extends to at least one adjacent sub-pixel region, and a color of a sub-pixel evaporated in a sub-pixel region corresponding to the evaporation through-hole is different from a color of a sub-pixel evaporated in the at least one adjacent sub-pixel region;
the plurality of evaporation sources are disposed on one side of the evaporation mask distal to the to-be-evaporated substrate of a display panel, and the plurality of evaporation sources are arranged at intervals along a direction parallel to the to-be-evaporated substrate;
wherein a nozzle of each evaporation source faces the evaporation mask, the evaporation source is configured to evaporate a material onto a sub-pixel region of the to-be-evaporated substrate through the evaporation through-hole in the evaporation mask so as to form a sub-pixel, and materials evaporated by respective evaporation sources are different;
and an evaporation angle is formed between the nozzle of the evaporation source and the to-be-evaporated substrate, and a difference value between the evaporation angle and the through-hole angle of the evaporation through-hole is less than a difference threshold.

16. The evaporation device according to claim 15, wherein the evaporation device comprises two evaporation sources; the evaporation through-hole comprises two through-hole angles disposed oppositely in the direction parallel to the to-be-evaporated substrate; and
the evaporation angle of each evaporation source is equal to one, closer to the evaporation source, of the two through-hole angle of the evaporation through-hole.

17. The evaporation device according to claim 15, wherein a distance between each two adjacent evaporation sources is negatively correlated with a first parameter and is positively correlated with a second parameter;
wherein the first parameter is the thickness of the mask plate in the evaporation mask; the second parameter is a product of a first sub-parameter and a second sub-parameter; and
the first sub-parameter is, for each two adjacent evaporation sources, a distance between an intersection of a nozzle extension line of one evaporation source and a side of the evaporation through-hole distal to the to-be-evaporated substrate and an intersection of a nozzle extension line of another evaporation source and the side of the evaporation through-hole distal to the to-be-evaporated substrate, and the second sub-parameter is a sum of the first parameter and a vertical distance between the plurality of evaporation sources and the evaporation mask.

18. The evaporation device according to claim 17, wherein the distance b between each two adjacent evaporation sources satisfies: b=a(d+Ts)/d;
where d is the first parameter, a is the first sub-parameter, and Ts is the vertical distance between the plurality of evaporation sources and the evaporation mask.

19. The evaporation device according to claim 15, wherein the cross-section of the evaporation through-hole is trumpet-shaped in the direction perpendicular to the to-be-evaporated substrate; and
a distance between each two adjacent evaporation sources is negatively correlated with a smallest through-hole angle of the two through-hole angles of the evaporation through-hole.

20. An evaporation method, comprising:
providing a to-be-evaporated substrate; and
evaporating a material on the to-be-evaporated substrate by adopting the evaporation device as defined in claim 15 to form a plurality of sub-pixels.
